(19) United States
(12) Patent Application Publication
(10) Pub. No.: US 2020/0358395 A1
(43) Pub. Date: Nov. 12, 2020

(54) QUICK INSTALLATION STRUCTURE OF SOLAR PANEL FOR OUTDOOR PRODUCT

(71) Applicant: ZHEJIANG YOTRIO GROUP CO.,LTD, Zhejiang (CN)

(72) Inventors: Youtao KE, Zhejiang (CN); Jianqiang XIE, Zhejiang (CN)

(73) Assignee: ZHEJIANG YOTRIO GROUP CO.,LTD, Zhejiang (CN)

(21) Appl. No.: 16/940,384

(22) Filed: Jul. 27, 2020

(30) Foreign Application Priority Data
May 27, 2020 (CN) 202020928935.7

(51) Int. Cl. H02S 40/36; F24S 25/20; H02S 20/00; H05K 1/11; H05K 1/14

(52) U.S. Cl. CPC H02S 40/36; F24S 25/20; H05K 1/141; H05K 1/117; H02S 20/00

(57) ABSTRACT

A quick installation structure of a solar panel for an outdoor product includes a top cover. A circuit board is installed inside the top cover, a through-cavity is disposed on the top cover, a live terminal block is disposed on the circuit board, and the live terminal block may quickly plug in and fit with an electrical connection terminal block through the through-cavity. The electrical connection terminal block is configured to electrically connect to the solar panel. The disclosure can realize the conductive quick connection and quick disconnection of the solar panel and the circuit board by optimizing the design and using the quick installation and quick disconnection structure of the live terminal block and the electrical connection terminal block.

### CROSS-REFERENCE TO RELATED APPLICATION

This application claims the priority benefit of China application serial no. 202020928935.7, filed on May 27, 2020. The entirety of the above-mentioned patent application is hereby incorporated by reference herein and made a part of this specification.

### BACKGROUND

### Technical Field

The present invention relates to the technical field of outdoor products, and in particular to a quick installation structure of a solar panel for an outdoor product.

### Description of Related Art

Outdoor products, usually outdoor furniture, refer to a series of appliances relative to indoor furniture that are set up in an open or semi-open outdoor space for the convenience of people's healthy, comfortable, and efficient public outdoor activities. The outdoor products mainly cover four categories of products: urban public outdoor furniture, courtyard outdoor leisure furniture, commercial place outdoor furniture, and portable outdoor furniture.

Products, such as sunshade umbrella, swing stand or outdoor awning, are often used outdoors due to their unique use functions. Many existing outdoor products will be configured with the devices, such as light strips, light bars, and voice boxes. Therefore, in order to facilitate outdoor use, the outdoor products will also be configured with corresponding solar means, such that it is convenient to realize the power supply to the above devices.

When installing the solar panel on the existing outdoor product, it is usually necessary to provide a hole on a side of the top cover, and draw a wire and a plug to connect the power supply from the internal circuit board to complete the power connection with the solar panel. However, the main defects of this structure are as follows. 1. The wire is exposed, which affects the appearance. 2. The wire and plug are exposed, and exposure under the sun and rain will cause them to age, which affects the service life and also easily cause short-circuit problems caused by leakage. 3. When the solar panel and the circuit board are docked for installation, the operation is relatively complicated.

### SUMMARY

The purpose of the present invention is to provide a quick installation structure of a solar panel for an outdoor product, which is used to solve the above technical problems. Therefore, the conductive quick connection and quick disconnection is achieved, which is convenient to install, and meanwhile the parts are completely built-in, thus they are not easily affected by external interference, thereby improving the service life and stability.

The technical problems solved by the present invention can be addressed by the following technical solutions.

A quick installation structure of a solar panel for an outdoor product includes a top cover. A circuit board is installed inside the top cover, a through-cavity is disposed on the top cover, an live terminal block is disposed on the circuit board, the live terminal block may quickly and removably plug in and fit with an electrical connection terminal block through the through-cavity, and the electrical connection terminal block is configured to electrically connect to the solar panel.

The solar panel is installed on an upper surface of a panel installing seat, a bottom portion of the panel installing seat is provided with a docking boss, a terminal through-cavity is disposed inside the docking boss, and the electrical connection terminal block is disposed in the terminal through-cavity.

The top cover comprises an upper nest top cover and an upper nest bottom cover, the upper nest top cover and the upper nest bottom cover cooperatively form, after being closed together, an inner cavity portion for installing the circuit board inside, and the through-cavity is disposed on the upper nest top cover.

An installation boss is disposed on an upper portion of the through-cavity, and limit clamping teeth are disposed on an inner cavity wall of the installation boss. The limit clamping teeth are configured to cooperate with alignment clamping teeth, and the alignment clamping teeth are disposed at a lower end portion of the docking boss.

The outdoor product is one of a sunshade umbrella, a swing stand or an outdoor awning.

The docking boss is embedded in an inner cavity of the installation boss, and the alignment clamping teeth and the limit clamping teeth are locked or unlocked by rotation.

The live terminal block is configured as a pin-type connector, and the electrical connection terminal block is configured as a pin-type interface.

The live terminal block is configured as a pin-type interface, and the electrical connection terminal block is configured as a pin-type connector.

The quick installation structure further comprises a top cap. An installation part is disposed in the top cap, and the installation part is configured to cooperate with the installation boss for installation.

The quick installation structure further comprises further a nest base, and an upper end of the nest base is used to cooperate with a lower end of an upper nest base for installation.

Compared with the prior arts, the present invention has the following outstanding advantages and effects. The present invention can realize the conductive quick connection and quick disconnection of the solar panel and the circuit board by optimizing the design and using the quick installation and quick disconnection structure of the live terminal block and the electrical connection terminal block. Combined with the docking boss and the installation boss, it is convenient to complete the alignment installation and improve the convenience of installation. At the same time, the conductive parts are completely built-in, and not easily affected by external interference, thereby improving the service life and stability.

The features of the present invention can be clearly understood by referring to the drawings of this case and the following detailed description of the preferred embodiments.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is an exploded schematic view of the overall sectional structure of the present invention;

FIG. 2 is an assembled schematic view of the overall sectional structure of the present invention;

FIG. 3 is a perspective view of the overall exploded structure of the present invention;

FIG. 4 is a schematic structural view of a panel installing seat of the present invention; and

FIG. 5 is a schematic structural view of an upper nest top cover of the present invention.

### DESCRIPTION OF THE EMBODIMENTS

In order to make the technical means, creative features, achievement goals and effects achieved by the present invention easy to understand, the present invention will be further described below in conjunction with specific illustrations.

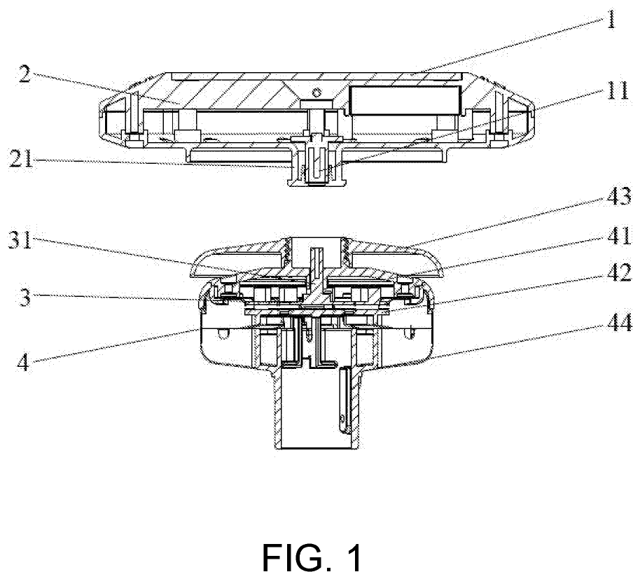

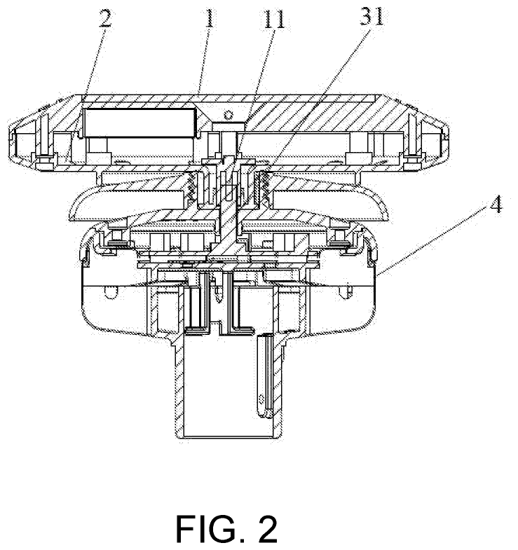

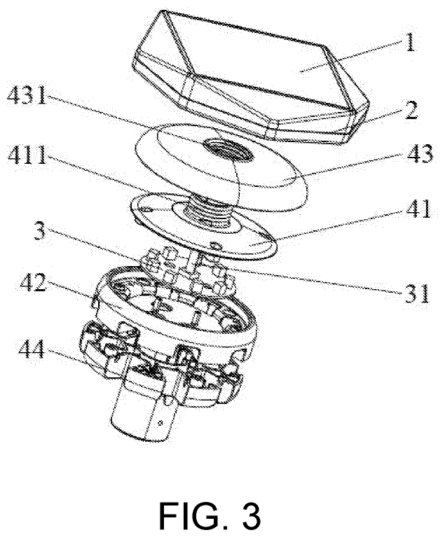

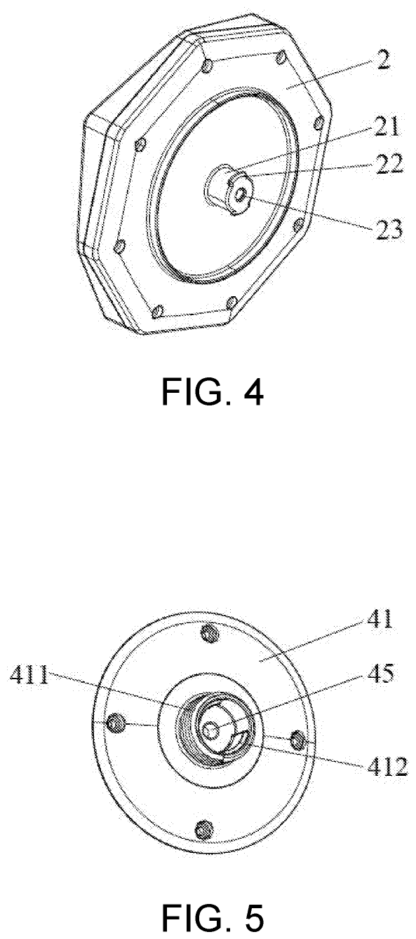

With reference to FIGS. 1-5, the present embodiment provides a quick installation structure of a solar panel for an outdoor product. The quick installation structure includes a top cover 4. A circuit board 3 is installed inside the top cover 4, a through-cavity 45 is disposed on the top cover 4, an live terminal block 31 is disposed on the circuit board 3, the live terminal block 31 may quickly and removably plug in and fit with an electrical connection terminal block 11 through the through-cavity 45, and the electrical connection terminal block 11 is configured to electrically connect to the solar panel 1.

Wherein, the live terminal block 31 is disposed in the middle of the circuit board 3 and is of a structure vertically extending upward. The live terminal block 31 extends upward from the through-cavity 45 of the lower port. In one embodiment, the live terminal block 31 is disposed inside the through-cavity 45, and is usually disposed in an inner cavity of the installation boss 411. In another embodiment, the live terminal block 31 penetrates upwardly through the through-cavity and extends to the outside. The electrical connection terminal block 11 is of a downward structure, which facilitates to achieve the quick connection with the live terminal block 31.

Preferably, the solar panel 1 is installed on an upper surface of a panel installing seat 2, a bottom portion of the panel installing seat 2 is provided with a docking boss 21, a terminal through-cavity 23 is disposed inside the docking boss 21, and the electrical connection terminal block 11 is disposed in the terminal through-cavity 23. The electrical connection terminal block 11 extends into the terminal through-cavity 45 to achieve the cooperative installation with the electrical connection terminal block 11.

In one embodiment, the top cover 4 comprises an upper nest top cover 41 and an upper nest bottom cover 42. The upper nest top cover 41 and the upper nest bottom cover 42 cooperatively form, after being closed together, an inner cavity portion for installing the circuit board 3 inside, and the through-cavity 45 is disposed on the upper nest top cover 41. An installation boss 411 is also disposed on an upper portion of the through-cavity 45, and limit clamping teeth 412 are disposed on an inner cavity wall of the installation boss 411, the limit clamping teeth 412 are configured to cooperate with alignment clamping teeth 22, and the alignment clamping teeth 22 are disposed at a lower end of the docking boss 21. The docking boss 21 is configured to cooperate with the installation boss 411, the docking boss 21 is embedded in an inner cavity of the installation boss 411, and the alignment clamping teeth 22 and the limit clamping teeth 412 are locked or unlocked by rotation. Preferably, the rotation arc is usually π/4.

In one embodiment, the outdoor product is one of a sunshade umbrella, a swing stand or an outdoor awning.

In one embodiment, the live terminal block 31 is configured as a pin-type connector, and the electrical connection terminal block 11 is configured as a pin-type interface.

In one embodiment, the live terminal block 31 is configured as a pin-type interface, and the electrical connection terminal block 11 is configured as a pin-type connector.

Wherein, the pin-type connector and pin-type interface are usually connected by male and female wires in the prior art.

In one embodiment, the quick installation structure further comprises a top cap 43. An installation part 431 is disposed in the top cap 43, the installation part 431 is configured to cooperate with the installation boss 411 for installation, preferably using screw to install, and the top cap 43 is configured to improve the overall decoration effect.

In one embodiment, the quick installation structure further comprises a nest base 44. An upper end of the nest base 44 is used to cooperate with a lower end of an upper nest base 42 for installation. The nest base 44 may be an umbrella tray, which is convenient for docking with the umbrella post for installation. In one embodiment, the nest base 44 may also be a mounting bracket, which is convenient to fixedly install to a swing stand. In one embodiment, the nest base 44 may also be a roof base, which is convenient for installation in cooperation with the roof rod.

The operation principle of the present invention is as follows. Completing the fixed installation of the top cap, the upper nest top cover, the upper nest bottom cover and the nest base, wherein the circuit board is built-in and installed between the upper nest top cover and the upper nest bottom cover. Through the docking of the docking boss and the installation boss, when the live terminal block and the electrical connection terminal block are docked, the panel installing seat is rotated to lock the alignment clamping teeth and the limit clamping teeth, thereby completing the fixation and completing the conduction of solar panel and circuit board.

The disclosure can realize the conductive quick connection and quick disconnection of the solar panel and the circuit board by optimizing the design and using the quick installation and quick disconnection structure of the live terminal block and the electrical connection terminal block. Combined with the docking boss and the installation boss, it is convenient to complete the alignment installation and improve the convenience of installation. At the same time, the conductive parts are completely built-in, and not easily affected by external interference, thereby improving the service life and stability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A quick installation structure of a solar panel for an outdoor product, the quick installation structure comprising a top cover, wherein a circuit board is installed inside the top cover, a through-cavity is disposed on the top cover, an live terminal block is disposed on the circuit board, the live terminal block is capable of removably plugging in and fitting with an electrical connection terminal block through the through-cavity, and the electrical connection terminal block is configured to electrically connect to the solar panel.

2. The quick installation structure of the solar panel for the outdoor product according to claim 1, wherein the solar panel is installed on an upper surface of a panel installing seat, a bottom portion of the panel installing seat is provided with a docking boss, a terminal through-cavity is disposed inside the docking boss, and the electrical connection terminal block is disposed in the terminal through-cavity.

3. The quick installation structure of the solar panel for the outdoor product according to claim 1, wherein the top cover comprises an upper nest top cover and an upper nest bottom cover, the upper nest top cover and the upper nest bottom cover cooperatively form, after being closed together, an inner cavity portion for installing the circuit board inside, and the through-cavity is disposed on the upper nest top cover.

4. The quick installation structure of the solar panel for the outdoor product according to claim 3, wherein an installation boss is disposed on an upper portion of the through-cavity, and limit clamping teeth are disposed on an inner cavity wall of the installation boss, the limit clamping teeth are configured to cooperate with alignment clamping teeth, and the alignment clamping teeth are disposed at a lower end portion of the docking boss.

5. The quick installation structure of the solar panel for the outdoor product according to claim 1, wherein the outdoor product is one of a sunshade umbrella, a swing stand or an outdoor awning.

6. The quick installation structure of the solar panel for the outdoor product according to claim 4, wherein the docking boss is embedded in an inner cavity of the installation boss, and the alignment clamping teeth and the limit clamping teeth are locked or unlocked by rotation.

7. The quick installation structure of the solar panel for the outdoor product according to claim 6, wherein the live terminal block is configured as a pin-type connector, and the electrical connection terminal block is configured as a pin-type interface.

8. The quick installation structure of the solar panel for the outdoor product according to claim 6, wherein the live terminal block is configured as a pin-type interface, and the electrical connection terminal block is configured as a pin-type connector.

9. The quick installation structure of the solar panel for the outdoor product according to claim 4, the quick installation structure further comprising a top cap, wherein an installation part is disposed in the top cap, and the installation part cooperates with the installation boss for installation.

10. The quick installation structure of the solar panel for the outdoor product according to claim 9, the quick installation structure further comprising a nest base, an upper end of the nest base cooperates with a lower end of an upper nest base for installation.
